(19) United States
(12) Patent Application Publication
(10) Pub. No.: US 2016/0057878 A1
(43) Pub. Date: Feb. 25, 2016

(54) Protective Structure and Electronic Device Thereof

(71) Applicant: Wistron Corporation, New Taipei City (TW)

(72) Inventors: Chia-Cheng SU, New Taipei City (TW); Po-Yuan HSU, New Taipei City (TW); Tsung-Hsien CHEN, New Taipei City (TW); Ping-Feng LIAO, New Taipei City (TW); Hsing-Wang CHANG, New Taipei City (TW)

(21) Appl. No.: 14/746,297

(22) Filed: Jun. 22, 2015

(30) Foreign Application Priority Data
Aug. 25, 2014 (TW) 103129249

(51) Int. Cl. H05K 5/06; H05K 5/00

(52) U.S. Cl. CPC H05K 5/061; H05K 5/0008; H05K 5/069

(57) ABSTRACT

An electronic device includes an electronic module and a protective structure. A protective structure includes a first housing, a second housing and an elastic body. The first housing has a first side face, the first side face has a first normal direction. The second housing has a second side face, the second side face has a second normal direction. The second housing and the first housing are fixed with a fixing direction. A containing portion is formed between the first side face and the second side face, the first normal direction and the second normal direction un-parallel the fixing direction. The elastic body has a resisting portion, the resisting portion sets in the containing portion. The resisting portion abuts against the second side face.

### BACKGROUND OF THE INVENTION

1. Field of the Invention

The present invention relates to a protective structure and an electronic device thereof. In addition, the protective structure and the electronic device thereof achieve the purpose of proofing water according elastic body.

2. Description of the Related Art

With the development of the electronic product, the electronic product is more precise and closely links with people life. However, no matter how the electronic product develops, the electronic element can't touch liquid. If the liquid goes into the region the electronic: element set in, the electronic product is damaged, even never used. Therefore, the present industry works for water-proofing design.

Presently, the water-proofing design is setting an elastic body between the fixing face of two housings, it means the elastic body bear a pressure in same direction with the housing fixing direction, called “positive pressure”. The elastic body abuts the housing by the positive pressure, so the liquid can't go into the shell though the seam. However, in the protective structure formed by the positive pressure, the shell shape (undulation, curve . . . etc.) may make the elastic body buckle, and the elastic body can't completely abut against the fixing face. Therefore, it's necessary to provide a batter protective structure having water-proofing function to solving the mistake of reference.

### SUMMARY OF THE INVENTION

The present invention solves the problem which is providing a protective structure with better water-proofing.

For solving the problem said above, the present invention provides a protective structure which includes a first housing, a second housing and a elastic body. The first housing has a first side face, the first side face has a first normal direction. The second housing has a second side face, the second side face has a second normal direction. The second housing and the first housing are fixed with a fixing direction. A containing portion is formed between the first side face and the second side face, the first normal direction and the second normal direction un-parallel the fixing direction. The elastic body has a resisting portion, the resisting portion sets in the containing portion. The resisting portion abuts against the second side face.

The present invention also provides an electronic device which has said protective structure.

According to said embodiment, the protective structure of the present at least has the advantage below: by the resisting portion of the elastic body clamped between the first housing and the second housing by side pressure, the liquid is difficult to go into, and it avoids affecting the elastic body abutting the first housing and the second housing by the outline of shell.

### BRIEF DESCRIPTION OF THE DRAWINGS

These and other objects and advantages of the present invention will become apparent from the following description of the accompanying drawings, which disclose several embodiments of the present invention. It is to be understood that the drawings are to be used for purposes of illustration only, and not as a definition of the invention.

In the drawings. Wherein similar reference numerals denote similar elements throughout the several views:

FIG. 1 is an exploding diagram of the electronic: device of the present invention.

FIG. 2 is a composing diagram of the protective structure of the present invention.

FIG. 3 is a cross section diagram of composition of the protective structure of the present.

FIG. 4 is a cross section diagram of composition of the protective structure of the present second embodiment.

FIG. 5 is a cross section diagram of composition of the protective structure of the present third embodiment.

### DETAILED DESCRIPTION OF THE PREFERRED EMBODIMENT

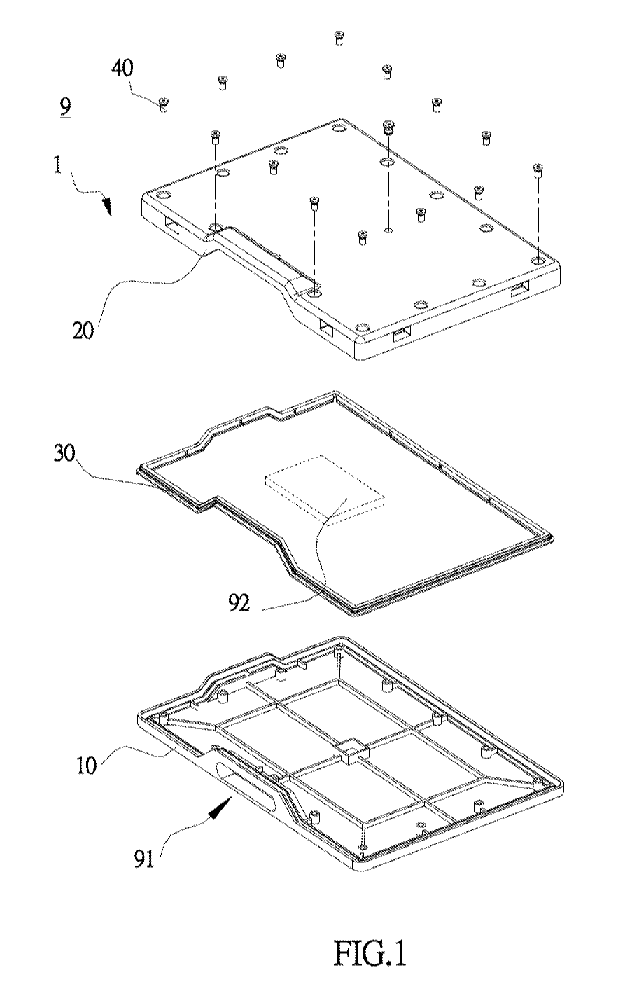

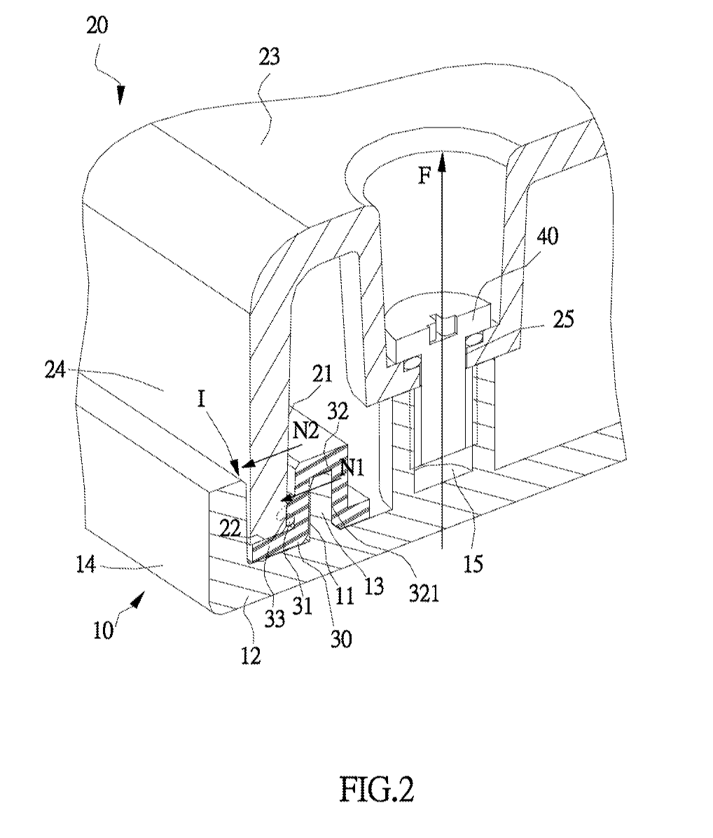

As shown in FIG. 1, the present invention provides a protective structure 1, which is applied on a electronic device 9, for example: cellphone, camera, pad computer, earphone . . . etc. Particularly, the protective structure is further applied on the electronic device 9 which has water-proofing and dust-proofing requests. As shown in FIG. 2, the protective structure 1 comprises a first housing 10, a second housing 20 and elastic body 30, the first housing 10 and the second housing 20 is fixed each other along a fixing direction, and a containing portion I is formed between the first housing 10 and the second housing 20. The elastic body is set in the containing portion.

In the present embodiment, the first housing 10 and the second housing 20 are composed to form a closed container for providing a circuit board (not shown in figure), an electronic element(not shown in figure). It is not limited in the present invention whether or not the first housing 10 and the second housing 20 are composed. The first housing 10 and the second housing 20 also can be a part of the shell of product. The first housing 10 and the second housing 20 are provided for combining two elements.

As shown in FIG. 2, the first housing 10 has a first side face 11 and a first bottom face 12, the first side face 11 has a first normal direction N1, the first normal direction N1 and the fixing direction F are not parallel. In the present embodiment, the first normal direction N1 and the fixing direction F are substantially vertical. The first side face 11 is vertically extended from the first bottom face 12 substantially. It need to take note that the angle between the first normal direction N1 and the fixing direction F is not limited to said above, it is available to adjust by practically demand. The present invention embodiment, the first housing 10 including a assemble wall 113, a first outer wall 14 and a fixing column 15. The first outer wall 14 is the wall for forming the outline of the first housing 10. The assemble wall 13 is set at the inner circle of the first outer wall 14 with interval. The fixing column 15 is set at the inner circle of the assemble all 13. In the present invention embodiment, the fixing column 15 is a screw bolt, and, the face of the assemble wall 13 which face to the first outer wall 14 is the first side face 11.

As shown in FIG. 1, the second housing 20 has a second side face 21 and a second bottom face 22, the second side face 21 has a second normal direction N2, the second normal direction N2 and the fixing direction F are not parallel. In the present embodiment, the second normal direction N2 and the fixing direction F are substantially vertical. It need to take note that the angle between the second normal direction N2 and the fixing direction F is not limited to said above, it is available to adjust by practically demand. In the present invention embodiment, the second housing 20 includes a second outer wall and a plurality of fixing holes 25, the inner face of the second outer wall is the second side face 21. The fixing hole 25 is corresponding to the fixing column 15, and the fixing hole 25 is a screw hole, in the present invention.

As shown in FIGS. 2 and 3, the elastic body 30 includes a resisting portion 31, a assemble wall 32 and an extensive resisting portion 33. The resisting portion 31 has a length L. In the present invention embodiment, the extensive resisting portion 32 and the assemble wall 32 are a rubber string collectively, the resisting portion 31 is protruded and extended from the outer face of the assemble 32 to the extensive resisting portion 33. The assemble wall 32 is corresponding to the assemble wall 13, the assemble wall 32 is substantially converted-U shape to form a assemble space 321, it make the elastic body 30 be a combination of L shape and converted-U shape, the elastic body 30 is shown as a structure which has many curve. And, the resisting portion 31 is long strip and has a lengthwise direction T. A height H is from the crossing point, is formed via the intersection of the first side face 11 and the lengthwise direction T, to the extensive resisting portion 33. On the other word, the crossing point is formed via, the intersection of the first side face 11 and the lengthwise direction T. The height H is from the crossing point to the first bottom face 12. The height H is bigger than the length L.

As shown in FIG. 2, in assembling, the assemble wall 32 is set on the assemble wall 13, it means the assemble wall 13 is arrange on the place space, to fix the position of the elastic body 30 and the first housing 10. At least one fixing component 40 set through the fixing hole 25 to fix the fixing column 15 for fixing the first housing 10 and the second housing 20. The first side face 11 and the second side face 21 are set face to face to form the containing portion I, and the elastic body 30 is set in the containing portion I in slightly deforming. The abutting face 22 of the second housing 20 and the first bottom face 12 collectively squeeze the extensive resisting portion 33. The pressure of the extensive resisting portion 33 and the fixing direction are in the same direction, it means “positive pressure”.

As shown in FIG. 2, the resisting portion 31 is press against the assemble wall 13 and the second side face 21 through the assemble wall 32. The pressure of the resisting portion 31 and the fixing direction F are substantially vertical. It means the pressure of the resisting portion 31 is “side pressure”. The side pressure and the fixing direction F are vertical, so it avoids the resisting portion 31 and the second side face 21 are separated by the slight movement between the first housing 10 and the second housing 20. Referring to FIG. 1, when the resisting portion 31 is unstressed, the lengthwise direction T of the resisting portion 31 and the first normal direction N1 have an angle Θ between. When the resisting portion 31 is arranged on the containing portion I, the angle Θ make the resisting portion 31 squeezed bend to the first bottom face 12, to increase the abutting area between the resisting portion 31 and the second side face 21. The resisting portion 31 further extends to the first bottom face 11. Accordingly, in installing the second housing 20, the second housing 20 is installed along with the resisting portion 31 to avoid over pushing the resisting portion 31, and decrease the using life of the resisting portion 31. In the present invention embodiment, the angle Θ is 0 degree to 70 degree, for a better, is 50 degree to 60 degree.

Referring to said above, the height H from the crossing point, between the resisting portion 31 and the assemble wall 32, to the extensive resisting portion 33 is bigger than the length L of the resisting portion 31. It means the height from the crossing point, between the first side face 11 and the lengthwise direction T of the resisting portion 31, to the first bottom face 21 is bigger than the length of the resisting portion 31. Therefore, in hearing the side force, the resisting portion 31 is difficult to warp, and even the resisting portion 31 are bended by the side pressure, the resisting portion 31 doesn't abut against the extensive resisting portion 33, it avoids the squeezing, causing the assemble wall 32 displace, between the resisting portion 31 and the extensive resisting portion 33. Accordingly, the resisting portion 31 can't smoothly abut on the second side face 21.

As said above, the elastic body 30 abuts against the abutting face 22 and the second side face 21 of the second housing 20 to forming a proofing path W. When the outside liquid wants to go into the seam of the second side face 21 and the abutting face 22, the liquid shall be block by the proofing path W The proofing path W bears the positive pressure and the side pressure, and the two forces with different directions; therefore the protective structure 1 has batter water-proofing effect. As said above, the angle Θ between the lengthwise direction T and the first normal direction N1 makes the abutting area of the resisting portion 31 and the second side face 21 increase, furthermore, it increases the proofing path W. By the proofing path W formed by the side pressure, the water-proofing effect is difficult to be affected by the shape of the first housing 10 and the second housing 20.

Referring to FIG. 1, in the present embodiment, the electronic device 9 has an undulating part 91 formed with the first housing 10 and the second housing 20 collectively matching. If the positive pressure is only way to proof water, the partial elastic body 30 in the undulating part 91 is bended by undulation, and the partial elastic body 30 in the undulating part 91 dose not abut against the first housing 10 and the second housing 20. And according to the side pressure for proofing water, the elastic body 30 dose not be affected by the undulating part 91. The electronic device 9 includes an electronic: module 92, the electronic module 92 is placed between the first housing 10 and the second housing 20. The electronic module 92 changes the forming content according to the different electronic device 9. For example, if electronic device 9 is pad computer. the electronic module 92 includes touch panel, CPU and louder . . . etc.

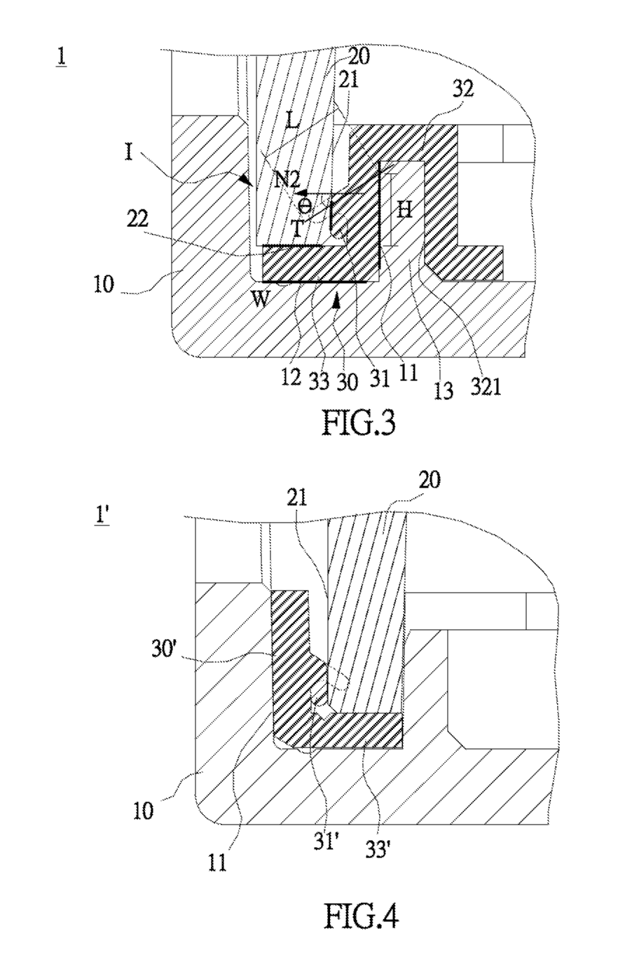

Referring to FIG. 4, in the present invention second embodiment, the elastic body 30′ of the protective structure 1′ only has the resisting portion 31′ and the extensive resisting portion 33′, and be directly clamped in the containing portion I without the assemble wall 32 and the assemble wall 13 fixing.

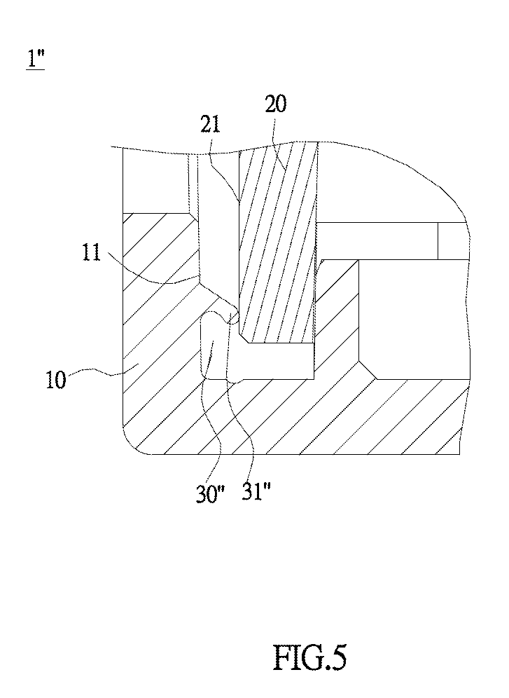

Referring to FIG. 5, in the present invention third embodiment, the elastic body 30″ of the protective structure 1″ only has the resisting portion 31″, it makes the resisting portion 31″ is directly inlaid in the first side face 11, means the resisting portion 31 is extended from the first side face 11. This structure can be formed by the double injection. So the protective structure 1″ only has the proofing path W formed from the side pressure,

To sum up, the protective structure of the present invention at least has the advantage below: by the resisting portion of the elastic, body clamped between the first housing and the second housing by side pressure, the liquid is difficult to go into, and it avoids affecting the elastic body abutting the first housing and the second housing by the outline of shell.

With the design of the present invention, typical memory cards can be integrated with the storage device of the computer to expand the storage space of the computer, and the application software can perform file management in the computer storage space. When the storage space of the original memory card is insufficient, the method of the present invention can be used for upgrading the original memory card to another memory card with a larger storage space for convenience.

Although the present invention has been explained in relation to its preferred embodiment, it is also of vital importance to acknowledge that many other possible modifications and variations can be made without departing from the spirit and scope of the invention as hereinafter claimed.

What is claimed is:

1. A protective structure, comprising:
a first housing, comprising a first side face, the first side face having a first normal direction;
a second housing, comprising a second side face, the second side face having a second normal direction, the second housing and the first housing being fixed along a fixing direction, a containing portion forming between the first side face and the second side face, the first normal direction and the second normal direction being not parallel to the fixing direction; and
an elastic body, comprising a resisting portion, the resisting portion being set in the containing portion, the resisting portion abutting against the second side face.

2. The protective structure as claimed in claim 1, wherein the resisting portion is long strip, the resisting portion has a lengthwise direction, when the resisting portion is unstressed, an angle is formed between the lengthwise direction and the second normal direction, and when the resisting portion is deformed, it is abutted against the second side face.

3. The protective structure as claimed in claim 2, wherein the first normal direction and the second normal direction are substantially vertical with the fixing direction.

4. The protective structure as claimed in claim 3, wherein the first housing comprises a first bottom face, the first side face being substantially vertical with the first bottom face and extends from the first bottom face.

5. The protective structure as claimed in claim 4, wherein a crossing point is formed via the intersection of the first side face and the lengthwise direction, and a vertical length from the crossing point to the first bottom face is longer than a length of the resisting portion.

6. The protective structure as claimed in claim 5, wherein the resisting portion extends toward the first bottom face.

7. The protective structure as claimed in claim 6, wherein the angle is between 50 degree and 60 degree.

8. The protective structure as claimed in claim 7, wherein the first housing comprises a assemble wall the assemble wall sets at the assemble wall.

9. The protective structure as claimed in claim 8, wherein the assemble wall is convexly set on the inner face of the first housing, the assemble wall is substantially converse-U shape to form a assemble space, the assemble wall being set in the assemble space.

10. The protective structure as claimed in claim 1, wherein the second housing comprises an abutting face, the elastic body comprises an extensive resisting portion, and the extensive resisting portion is pressed between the abutting face and the first bottom face.

11. The protective structure as claimed in claim 10, wherein the elastic body is inlaid in the first side face.

12. An electronic device, comprising:
an electronic module; and
a protective structure, comprising:
a first housing, comprising a first side face, the first side face having a comprising first normal direction;
a second housing, comprising a second side face, the second side face having a second normal direction, the second housing and the first housing being fixed along a fixing direction, a containing portion forming between the first side face and the second side face, the first normal direction and the second normal direction being not parallel to the fixing direction; and
an elastic body, comprising a resisting portion, the resisting portion being set in the containing portion, the resisting portion abutting against the second side face;
wherein, the electronic module is set between the first housing and the second housing.

13. The electronic device as claimed in claim 12, wherein the resisting portion is long strip, the resisting portion has a lengthwise direction, when the resisting portion is unstressed, an angle is formed between the lengthwise direction and the second normal direction, and when the resisting portion is deformed, it is abutted against the second side face.

14. The electronic device as claimed in claim 2, wherein the first normal direction and the second normal direction are substantially vertical with the fixing direction.

15. The electronic device as claimed in claim 14, wherein the first housing comprises a first bottom face, the first side face being substantially vertical with the first bottom face and extends from the first bottom face, a crossing point is formed via the intersection of the first side face and the lengthwise direction, and a vertical length from the crossing point to the first bottom face is longer than a length of the resisting portion.

16. The electronic device as claimed in claim 15, wherein the resisting portion extends toward the first bottom face, the angle is between 50 degree and 60 degree.

17. The electronic device as claimed in claim 16, wherein the first housing comprises a assemble wall, the assemble wall sets at the assemble wall, the assemble wall is convexly set on the inner face of the first housing, the assemble wall is substantially converse-U shape to form a assemble space, the assemble wall being set in the assemble space.

18. The electronic device as claimed in claim 12, wherein the second housing comprises an abutting face, the elastic body comprises an extensive resisting portion, and the extensive resisting portion is pressed between the abutting face and the first bottom face.

19. The protective structure as claimed in claim 18, wherein the elastic body is inlaid in the first side face.

20. The electronic device as claimed in claim 12, wherein the first housing and the second housing collectively form a undulating part.
